(19) United States
(12) Patent Application Publication
(10) Pub. No.: US 2013/0222019 A1
(43) Pub. Date: Aug. 29, 2013

(54) SEMICONDUCTOR INTEGRATED CIRCUIT, SEMICONDUCTOR DEVICE, AND METHOD OF DESIGNING SEMICONDUCTOR INTEGRATED CIRCUIT

(71) Applicants: Toshiki SESHITA, Kawasaki-shi (JP); Hirotsugu Wakimoto, Kawasaki-shi (JP)

(72) Inventors: Toshiki SESHITA, Kawasaki-shi (JP); Hirotsugu Wakimoto, Kawasaki-shi (JP)

(73) Assignee: Kabushiki Kaisha Toshiba, Tokyo (JP)

(21) Appl. No.: 13/596,252

(22) Filed: Aug. 28, 2012

(30) Foreign Application Priority Data
Feb. 28, 2012 (JP) 2012-41986

(51) Int. Cl. H03L 7/00; G06F 17/50

(52) U.S. Cl. 327/143; 716/119

(57) ABSTRACT

An semiconductor integrated circuit has a macro cell, an initial voltage setting unit to generate initial data to be set in the macro cell, and a data wiring section connected between the macro cell and the initial voltage setting unit so that the data wiring section is at a predetermined potential level.

### CROSS REFERENCE TO RELATED APPLICATIONS

This application Is based upon and claims the benefit of priority from the prior Japanese Patent Application No. 2012-41988, filed on Feb. 28, 2012, the entire contents of which are incorporated herein by reference.

### FIELD

Embodiments of the present Invention relate to a semiconductor integrated circuit, a semiconductor device, and a method of designing a semiconductor integrated circuit, each provided with a macro cell

### BACKGROUND

In a high frequency circuit of a mobile phone, a transmitter circuit and a receiver circuit are selectively connected to a common antenna via a switch circuit for high frequency signals. Conventionally, an HEMT (High Electron Mobility Transistor) using a compound semiconductor has been used for a switching device of such a switch circuit for high frequency signals. However, recently, due to a demand for low cost and compactness. It has been studied to replace an HEMT with an MOSFET (Metal Oxide Semiconductor Field Effect Transistor) formed on a silicon substrate.

Nevertheless, an MOSFET formed on an ordinary silicon substrate has a problem that a large parasitic capacitance Is generated between a source or drain electrode and a silicon substrate and a problem that a large power loss of high frequency signals occurs because silicon Is used as a material of a semiconductor. Therefore, a technique of forming a switch circuit for high frequency signals on an SOI (Silicon On Insulator) substrate has been proposed.

In recent years, mobile phones have advanced with multimode and multiband capabilities. Along with this advancement, the number of ports required for high frequency switches exceeds ten. When the number of the ports increases, inevitably, the number of bits, of a control signal for controlling the switch connection state is also increased. For example, in an SP10T switch that switches the connection state between an antenna terminal and ten RF terminals, switching control of ten connection states is required, and hence the number of bits required by a control signal is four. A parallel input manner for parallel input of a 4-bit control signal ordinarily requires four terminals. In contrast with this manner a serial input manner for inputting a serial data signal in synchronism with a clock signal is advantageous in that only one data Input terminal is required even if the number of ports increases. For this reason, although the parallel input manner has been a major trend for conventional high frequency switches, recently there is a growing demand for the serial input manner.

The serial input manner is also advantageous in that high frequency ICs other than high frequency switches can he controlled through the same data line. In such a ease where a plurality of ICs are connected to one serial data line, an ID is required for Identifying each IC Besides the ID information, registers for storing various control Information are provided. Generally, data to be stored in those registers are bidirectionally communicated.

Generally, those registers are given an initial value. Moreover, depending on the type of the registers, the registers require to be externally rewritable. For example, a register for an IC Identification ID described above is normally given an initial value. The IC Identification ID may be rewritten, depending on the operation mode of a mobile phone. For example, in the case where two ICs connected to the same data bus have to perform the same operation simultaneously, it is required beforehand to prepare the same IC Identification ID for the two ICs, in other words, the IC Identification ID has to be rewritten from outside.

Next, a manner of designing a high frequency IC having a high frequency circuit such as a high frequency switch circuit, a serial-to-parallel converter circuit, and a register unit will be explained.

Generally, a serial-to-parallel converter circuit and a register unit are designed in the form of one macro cell using standard ceils. In this case, automatic placement and routine) software is used. In this way, since an internal circuit in a macro cell is automatically generated. It Is difficult for a designer to recognize a detailed connection state of logic gates In the internal circuit. It is also difficult to perform any manual correction after design.

Now, we will assume a situation for after the design of a product (IC1), designing another product (IC2) in which only the IC Identification ID is different from that of the IC1. Even if only the IC identification IDs are different between the IC1 and IC2, the net list to be input in automatic placement and routing software is different between the IC1 and IC2. Therefore, in order to design a macro cell of the IC2, It is required to perform the automatic placement and routing once again. Performing the automatic placement and routing once again means that the macro cells of the IC1 and IC2 have different connection states, If connection states are different, delay times due to the connection are also different. Therefore, for example, important electrical characteristics, such as a setup time and a hold time, become different between the IC1 and IC2.

### BRIEF DESCRIPTION OF THE DRAWINGS

FIG. 1 is a block diagram showing a schematic configuration of a semiconductor device 2 having a built-in semiconductor integrated circuit 1 according to a first embodiment;

FIG. 2 is a view showing the output potential characteristics of a power-on reset circuit 4;

FIG. 3 is a view showing a truth table of a D-F & F;

FIG. 4 is a view showing one example of a macro cell 10 corresponding to a register built-in serial-to-parallel converter circuit 5;

FIG. 5 is a block diagram showing a schematic configuration of a semiconductor device 2 having a built-in semiconductor Integrated circuit 1 according to a second embodiment;

FIG. 6 is a view showing a macro cell 10 corresponding to a register built-in serial-to-parallel converter circuit 5 according to the second embodiment;

FIG. 7 is a block diagram showing a schematic configuration of a semiconductor device 2 having a built-in semiconductor integrated circuit 1 according to a third embodiment;

FIG. 8 is a view showing a macro cell 10 corresponding to a register built-in serial-to-parallel converter circuit 5 according to the third embodiment;

FIG. 9 is a block diagram showing a schematic configuration of a semiconductor device 2 having a built-in semiconductor integrated circuit 1 according to a fourth embodiment;

FIG. 10 is a view showing a macro cell 10 corresponding to a register built-in serial-to-parallel converter circuit 5 according to a fourth embodiment; and

FIG. 11 is a block diagram showing a schematic configuration of a high frequency block 21 of a radio communication apparatus according to a fifth embodiment.

### DETAILED DESCRIPTION

According to one embodiment of an semiconductor integrated circuit has a macro cell, an initial voltage setting unit to generate initial data to be set in the macro cell, and a data wiring section connected between the macro cell and the initial voltage setting unit so that the data wiring section is at a predetermined potential level.

Embodiments will now be explained with reference to the accompanying drawings

### First Embodiment

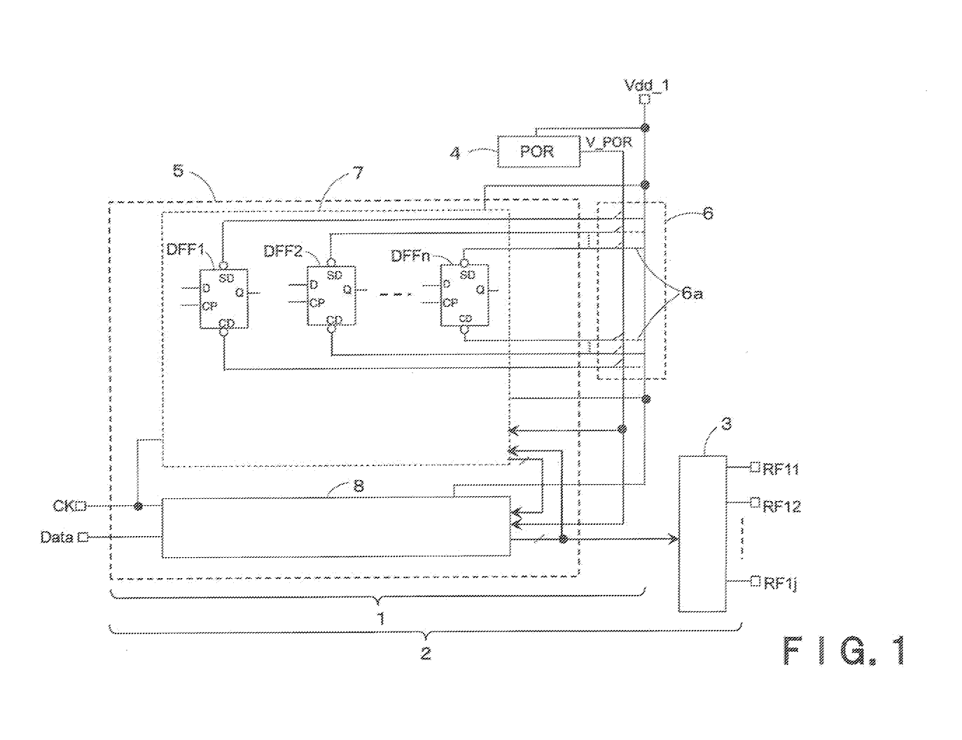

FIG. 1 Is a block- diagram showing a schematic configuration of a semiconductor device 2 having a built-in semiconductor integrated circuit 1 according to a first embodiment. The semiconductor device 2 of FIG. 1 may be configured with one chip or a plurality of chips. Some parts of the semiconductor device 2 may be configured with discrete parts.

The semiconductor device 2 of FIG. 1 is mainly, provided with a high frequency circuit 3 and a control circuit 1. The high frequency circuit 3 is, for example, a high frequency switch circuit for selecting one RF signal terminal from a plurality of RF signal terminals RF1 to RFn and connecting the selected terminal to an antenna terminal RF_COM. These RF signal terminals RF1 to RFn are connected to a transmitter & receiver circuit not shown in FIG. 1. The transmitter & receiver circuit is compatible with a plurality of radio systems and generates an RF signal unique to each radio system. As described later, at least one semiconductor device 2 of FIG. 1 is installed in a radio communication apparatus. The high frequency circuit 3 is not necessarily limited to the high frequency switch circuit.

The control circuit 1 is a semiconductor integrated circuit 1 according to the first embodiment and provided with a power-on reset circuit (PGR) 4, a register built-in serial-to-parallel converter circuit 5, and a register initial-value setting unit 8.

The register built-in serial-to-parallel converter circuit 5 is generated by a macro cell using standard cells. The macro is automatically generated by using automatic placement and routing software.

A standard cell is an internal circuit cell such as a logic gate and a flip-flop previously registered in a library of automatic placement and routing software. The automatic placement and routing software selects any standard cell depending on the circuit to be designed and performs automatic placement and routing. The standard cell includes various cells each having known electrical characteristics such as signal propagation characteristics and parasitic capacitance. All standard cells are roughly unified in size. For example, by adjusting the height of all standard cells to be the same height, the height in the row direction becomes constant when a plurality of standard cells are aligned in the transverse direction. Therefore, it is possible to closely arrange many standard ceils over a plurality of rows, hence improving cell density.

The register built-in serial-to-parallel converter circuit 5 according to this embodiment is generated by a macro cell that is a combination of a plurality of standard cells. This macro cell is also registered in a library. Therefore, once the macro cell is generated, the macro cell can be used for another circuit later.

FIG. 2 is a view showing the output potential characteristics of the power-on reset circuit 4. As shown, when a power supply potential Vdd_of the semiconductor device 2 rises at a time T1, the power-on reset circuit 4 performs a processing of raising an output potential V_POR to high at a time T2 after the time T1. The output potential V_POR is referred to as a power-on reset potential, hereinafter.

Generally, the power-on reset circuit 4 is generated by manual placement and routing in conformity with the specifications of the semiconductor integrated circuit 1. However, the power-on reset circuit 4 may be preliminarily registered in a library in the form of a macro cell using standard cells.

As shown in FIG. 1, the serial-to-parallel converter circuit 5 is provided with a register unit 7 and a serial-to-parallel converter unit 8. The register unit 7 has a plurality of D-type flip-flops (hereinafter, D-F/F). Each P-F/F (DFF1 to DFFn) has a set terminal SP and a reset terminal CD. The potential setting at the set and reset terminals is performed by an initial-value setting unit (initial voltage setting unit) 6.

It is just an example to provide the D-F/Fs in the register unit 7. Another type of flip-flop may be provided. Moreover, various logic gates other than flip-flops may be arranged to perform a specific logic operation in the register unit 7.

In the following description, an example in which an n number (for example, four) of D-F/Fs (DFF1 to DFFn) each having a set terminal SD and a reset terminal CD are provided in the register unit 7 will be shown as a simple example,

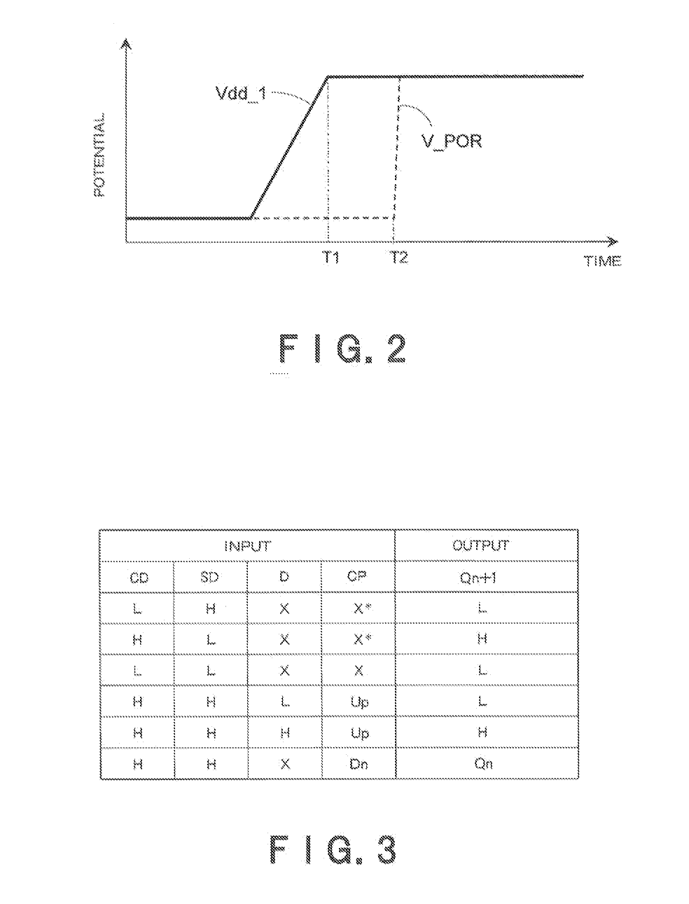

FIG, 3 is a view showing a truth table of a D-F/F in FIG. 3, H, L, X, Up, and Dn indicate logic high, logic low, don't care, a rising edge of a clock signal CP, and a failing edge of the clock signal CP, respectively. As shown, when the reset terminal CD is at low, the D-F/F is reset to output low. It is the principle of the D-F/F that when the set terminal SD is at low, the D-F/F is set to output high. However, when both of the set and reset terminals SD and CD are at low, the reset operation has priority and hence the output becomes low.

The register unit 7 holds ID information for identifying each semiconductor device 2 and various control information by using the n number of D-F/Fs (DFF1 to DFFn). There is no particular limitation to the type and the number of concrete information to be held by the register unit 7, information held by the register unit 7 can be retrieved from the outside of the semiconductor device 2. As described above, to hold initial information at the register unit 7 is performed via the register initial-value setting unit 6. However, the initial information may be continuously held in the register unit 7. Moreover, the initial information may be used for a specific logic operation by the register unit 7.

The serial-to-parallel converter unit 8 converts serial data DATA input from the outside of the semiconductor device 2 into parallel data in synchronism with a clock signal CK input from outside. For example, when the high frequency circuit 3 is an SPnT switch, the high frequency circuit 3 selects one of the RF signal terminals RF1 to RFn based on the parallel data. When the serial data DATA is encoded data, the data may be converted into parallel data and then decoded by a decoder (not shown) and then input to the high frequency circuit 3.

The high frequency circuit 3 builds in a drive circuit and a high frequency switch circuit (both not shown). After raising the electric potential level of parallel data output from the serial-to-parallel converter unit 3, the high frequency circuit 3 switches over the RF signal terminals.

As described above, at least a portion of information held by the register unit 7 is different in each semiconductor integrated circuit 1. Therefore, if macro cells are generated by automatic placement and routing software, including the information held by the register unit 7, all of the internal connections of generated macro cells become different from one another Electrical characteristics, such as the signal propagation characteristics, of the generated macro cells also become different from one another. In this case, different macro cells are used for a plurality of semiconductor integrated circuits 1. Therefore, operation verification has to be performed for each semiconductor integrated circuit 1. This leads to increase of the design and production costs.

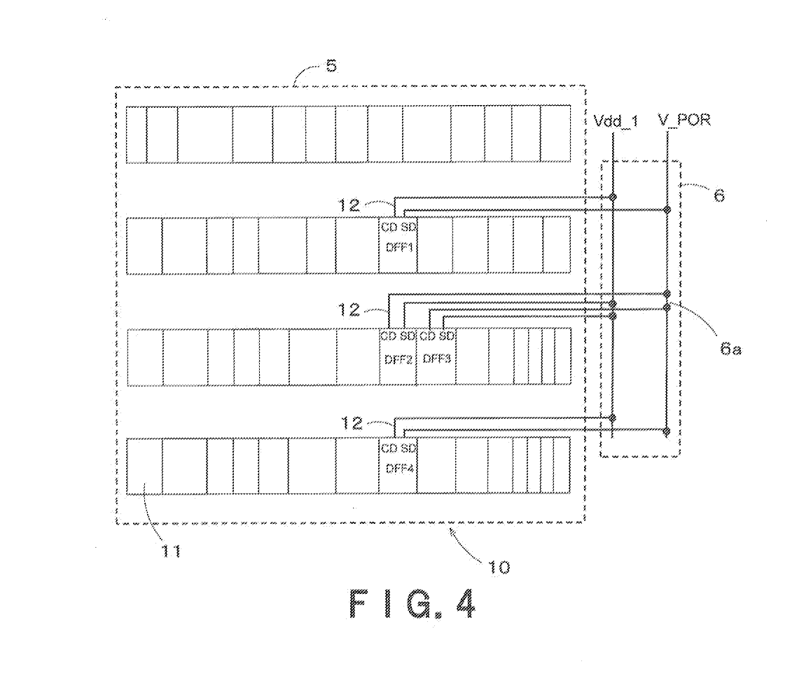

FIG. 4 is a view showing one example of a macro cell 10 corresponding to the register built-in serial--parallel converter circuit 5. The macro cell 10 of FIG. 4 is generated by using standard cells 11 preliminarily prepared in a library. The rectangular minimum unit in FIG. 4 is a standard cell 11 preliminarily registered in a library. A complete example of the standard cell 11 is a logic gate cell or a flip-flop such as a D-F/F. In FIG. 4, wiring patterns (data wiring sections) 12 run from the set terminals SD and the reset terminals CD of four D-F/Fs (DFF1 to DFF4) included in the register unit 7. The wiring patterns 12 are connected to the register initial-value setting unit 6 provided outside the macro cell 10.

A power supply line and a power-on reset line run through the register initial-value setting unit 6. The register initial-value setting unit 6 has a wiring connection unit 6a for manually connecting each wiring pattern 12 from the macro cell 10 to either of the power supply line and the power-on reset Line. For example, an operator performs connection one by one manually on the screen of a computer that executes automatic placement and routing software.

Therefore, the potentials at the set terminal SD and the reset terminal CD of each D-F/F in the register unit 7 can he set arbitrarily so that any initial data can be set to the register unit 7.

As described above, in the first embodiment, the automatic placement and routing for the register built-in serial-to-parallel converter circuit 5 are performed by automatic placement and routing using automatic placement and routing software, with no initial data being held at the register unit 7 in the register built-in serial-to-parallel converter circuit 5, to generate the macro cell 10 using the standard cell 11. It is supposed that internal configuration and electrical characteristics of all macro cells 10 are the same as one another when no initial data is held at the register unit 7. Therefore, one type of macro cell 10 can be equally used for all semiconductor integrated circuits 1. Accordingly, the number of macro cells 10 to be used for the semiconductor integrated circuits 1 can be decreased and the time required for the operation verification of the macro ceils 18 can also be shortened.

Moreover, the register initial-value setting unit 6 for setting initial data to the register unit 7 in the serial-to-parallel converter circuit 5 is provided near the macro cell 10, and the wiring patterns 12 from the set and reset terminals SD and CD of the register unit 7 in the macro cell 10 are connected to the register initial-value setting unit 6. Therefore, by manually performing the internal wiring in the register unit 7 for each semiconductor integrated circuit 1, different information can be held in each of the register units 7 in the macro cells 10 of the same type.

The register initial-value setting unit 6 is configured with a simple circuit on only the purpose of connecting a power supply line or a power-on reset line to the wiring patterns 12 running from the macro cell 10, and does not include any transistor. Therefore, the register initial-value setting unit 6 can be configured with a tiny circuit area without wastefully spending gates.

Therefore, according to the present embodiment, each of semiconductor integrated circuits 1 can be produced with a common macro cell 10. In addition, unique initial data can be set to the macro cell 10 in each semiconductor integrated circuit 1 by manually changing the internal connection of the register initial-value setting unit 8.

### Second Embodiment

In a second embodiment which will be described hereinbelow, the register initial-value setting unit 6 is provided in the register built-in serial-to-parallel converter circuit 5.

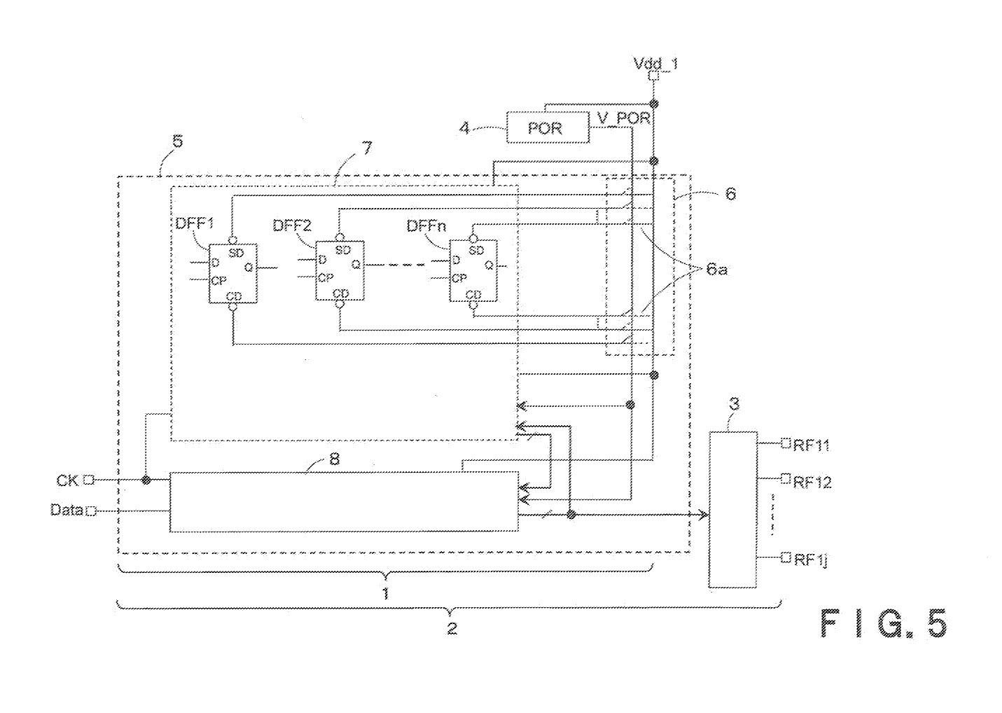

FIG. 5 is a block diagram showing a schematic configuration of a semiconductor device 2 having a built-in semiconductor integrated circuit 1 according to the second embodiment. In FIG. 5, the same elements as those in FIG. 1 are denoted by the same reference numbers. In the following, different features will be mainly explained.

The semiconductor integrated circuit 1 of FIG. 5 is different from FIG. 1 in that the register initial-value setting unit 6 is provided in the register built-in serial-to-parallel converter circuit 5, and the other configuration is the same as that of FIG. 1.

In the first embodiment, the entire register built-in serial-to-parallel converter circuit 5 is configured in the form of the macro cell 10 by the automatic placement and routing software. On the other hand, in the second embodiment, the register initial-value setting unit 6 in the serial-to-parallel converter circuit 5 is set to an automatic placement-and-routing prohibited area and then a macro cell 10 is generated by automatic placement and routing software for the remaining circuit section.

In more detail, in terms of the register initial-value setting unit 8 in the serial-to-parallel converter circuit 5, a standard cell 11 in which input and output terminals only are defined with no internal connection, is preliminarily registered in a library. Then, this standard cell 11 and other standard cells 11. In the serial-to-parallel converter circuit 5 are combined to generate a macro cell 10. in this case, the inner section of the standard cell 11 in the register initial-value setting unit 6 is set to an automatic placement-and-routing prohibited area so that any wiring in the macro cell 10 is not placed in the standard cell 11 in the register initial-value setting unit 6f except for the wiring patterns (data wiring sections) 12 running from the register unit 7.

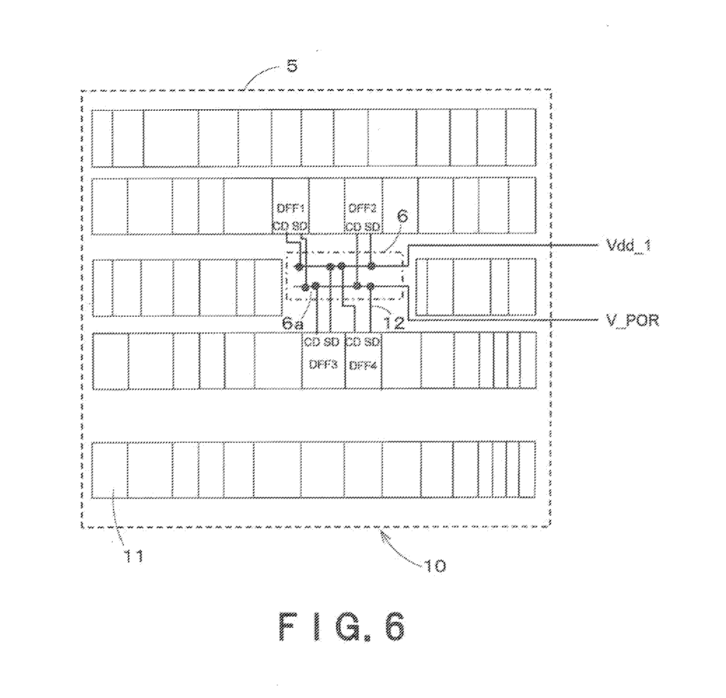

FIG. 6 is a view showing a macro cell 10 corresponding to the register built-in serial-to-parallel converter circuit 5 according to the second embodiment. In the example of FIG. 6, a register initial-value setting unit 6 is provided almost in the center of the macro cell 10. However, the register initial-value setting unit 8 can be provided in any area in the macro cell 10.

The macro cell 10 generated by the automatic placement and routing software has wiring patterns (initial data value wiring sections) 12 that run from the set terminals SO and the reset terminals CD of D-F/Fs (DFF1 to DFF4) to the register initial-value setting unit 6. A power supply line and a power-on reset line run through inside of the register initial-value setting unit 6. Therefore, in the same way as the first embodiment, by manual connection of the power supply line or the power-on reset line to each set terminal SD and each reset terminal CD in the register initial-value setting unit 6, it is possible to generate the register built-in serial-to-parallel converter circuits 5, each holding initial data different from each of the semiconductor integrated circuits 1.

As described above, in the second embodiment, when the register initial-value setting unit 8 is provided in the register built-in serial-to-parallel converter circuit 5, the area of the register initial-value setting unit 8 is set to an automatic placement-and-routing prohibited area, and then the entire register built-in serial-to-parallel converter circuit 5 is configured in the form of the macro cell 10 by the automatic placement and routing software. The macro cell 10 does not have any initial, data unique to each semiconductor integrated circuit 1. Therefore, the macro cell 10 can he commonly used for all semiconductor integrated circuits 1. In more detail, by manually setting the internal connection of the register initial-value setting unit 6. It is possible to generate the register built-in serial-to-parallel converter circuits 5, each holding initial data different from each of the semiconductor integrated circuits 1 while using the same macro cell 10.

### Third Embodiment

The first and second embodiments have shown an example in which D-F/Fs each having the set and reset terminals SD and CD are provided to the register unit 7 in the register built-in serial-to-parallel converter circuit 5. After a predetermined initial value is set to the register unit 7, a specific logical operation may be performed in the register unit 7. In other words, the register unit 7 does not only continuously hold a value set by the register initial-value setting unit 6, but also afterward changes the value once set in the register initial-value setting unit 6. In the third and fourth embodiments which will be described hereinbelow, the register unit 7 performs a specific logical operation using a value set by the register initial-value setting unit 6 to the register unit 7.

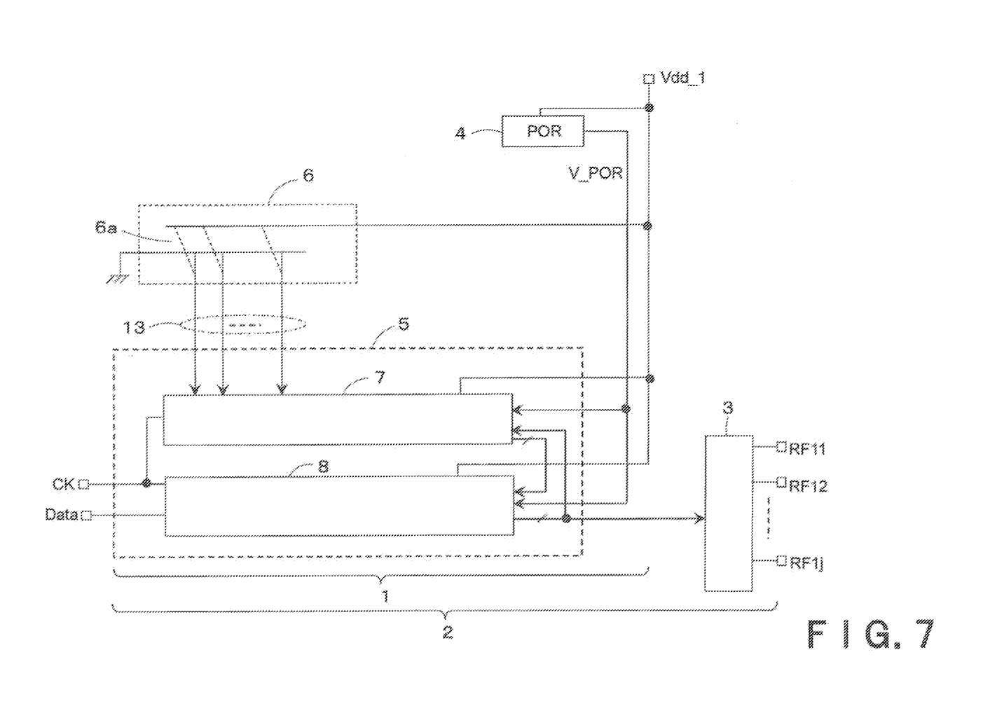

FIG. 7 is a block diagram showing a schematic configuration of a semiconductor device 2 having a built-in semiconductor integrated circuit 1 according to the third embodiment. In FIG. 7, the same elements as those in FIG. 1 are denoted by the same reference numbers. In the following, different features will be mainly described.

The difference of the semiconductor integrated circuit 1 of FIG. 7 from FIG. 1 is the internal configuration of the register unit 7 in the register built-in serial-to-parallel converter circuit 5. Although the internal configuration of the register unit 7 is not shown in FIG. 7, the register unit 7 performs a specific logical operation using an initial value set by the register initial-value setting unit 6. Therefore, logic gates are provided in the register unit 7. However, in addition to the logic gates, flip-flops may be provided according to need.

The register initial-value setting unit 6 is provided separate from the register built-in serial-to-parallel converter circuit 5. Inside of the register initial-value setting unit 6, a power supply line Vdd_1 and a ground line run through. The register initial-value setting unit 6 connects each of initial-value signal lines in an initial-value signal line group 13 to the power supply line Vdd_1 or the ground line. Accordingly, each of the initial-value signal lines in the initial-value signal line group 13 is set to a power or ground potential.

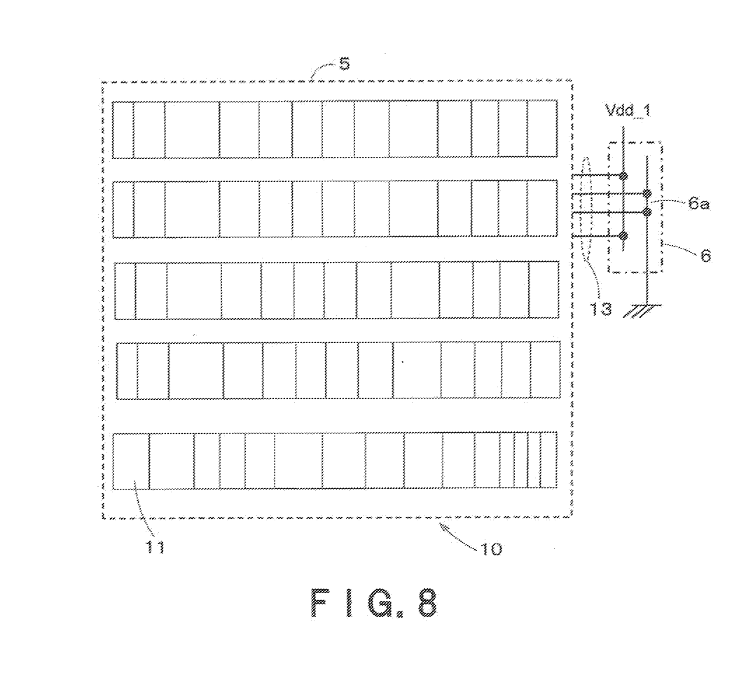

FIG. 8 is a view showing a macro cell 10 corresponding to a register built-in serial-to-parallel converter circuit 5 according to the third embodiment. As shown, the register initial-value setting unit 6 is provided near the macro cell 10. The register initial-value setting unit 8 has an initial-value signal line group 13 having the same number of initial-value signal lines as the number of the input signals of the register unit 7 in the macro cell 10.

As described above, in the third embodiment, the register initial-value setting unit 6 for generating a group of initial-value signals to be set to the register unit 7 in the register built-in serial-to-parallel converter circuit 5 is provided separate from the register built-in serial-to-parallel converter circuit 5, to generate the register built-in serial-to-parallel converter circuit 5 in the form of a macro cell 10 by automatic placement and routing software. Therefore, the generated macro cell 10 can be used for each semiconductor integrated circuit 1. Moreover, the internal connection of the register initial-value setting unit 6 is performed manually. Therefore, any initial value can be set to the register unit 7 in the register built-in serial-to-parallel converter circuit 5 for each semiconductor integrated circuit 1.

### Fourth Embodiment

In a fourth embodiment, different from the third embodiment, the register initial-value setting unit 6 is provided in the register built-in serial-to-parallel converter circuit 5.

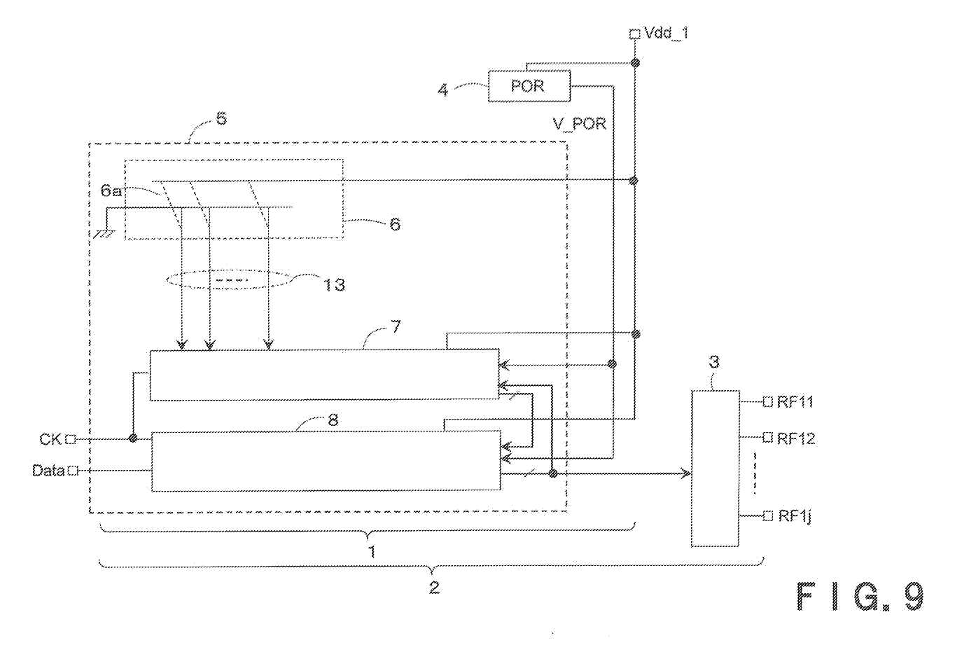

FIG. 9 is a block diagram showing a schematic configuration of a semiconductor device 2 having a built-in semiconductor integrated circuit 1 according to a fourth embodiment. In FIG. 9, the same elements as those in FIG. 7 are denoted by the same reference numbers. In the following, different features from FIG. 7 will be mainly explained.

The register built-in serial-to-parallel converter circuit 5 of FIG. 9 has the register initial-value setting unit 6 therein. The register initial-value setting unit 6 is set to an automatic placement-and-routing prohibited area. Therefore, when the register built-in serial-to-parallel converter circuit 5 is generated in the form of a macro cell 10 by the automatic placement and routing software, no internal connection is performed for the register initial-value setting unit 6 in the generated macro cell 10.

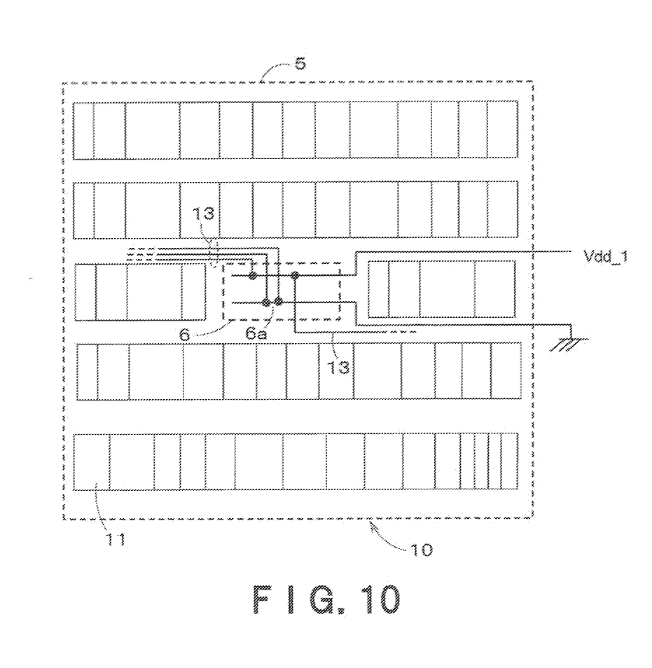

FIG. 10 is a view showing a macro cell 10 corresponding to a register built-in serial-to-parallel converter circuit 5 according to the fourth embodiment. The area of a register initial-value setting unit 6 is provided almost at the center of the macro cell 10. A power supply line and a power-on reset line run through the register initial-value setting unit 6. By manually connecting the initial-value signal lines in an initial-value signal line group 13 connected to the input signals of the register unit 7 in the register built-in serial-to-parallel converter circuit 5 to a power supply line Vdd_1 or a ground line, any initial value can be set to the register unit 7.

As described above, in the fourth embodiment, even when the register initial-value setting unit 6 is provided in the register built-in serial-to-parallel converter circuit 5. If the area of the register initial-value setting unit 6 is set to an automatic placement and routing prohibited area, and then the macro cell 10 is generated using the automatic placement and routing software, the generated macro cell 10 can be commonly used for a plurality of semiconductor integrated circuits 1.

### Fifth Embodiment

The semiconductor device 2 having the built-in semiconductor integrated circuit 1 described in the first to fourth embodiments may not he necessarily used singly. A plurality of semiconductor devices 2 may be connected to a common serial bus.

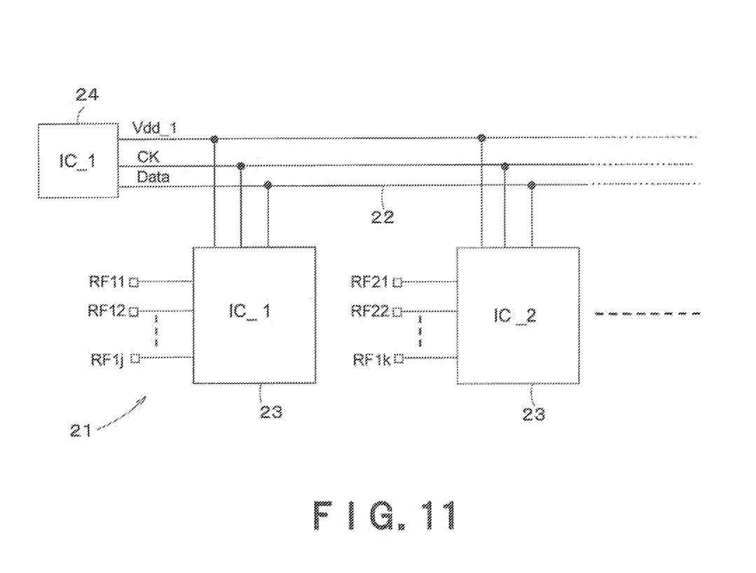

FIG. 11 is a block diagram showing a schematic configuration of a high frequency block 21 of a radio communication apparatus according to a fifth embodiment, The high frequency block 21 of the radio communication apparatus of FIG. 11 is provided with a plurality of high frequency ICs 23 connected to a common serial bus 22 and a control IC 24 also connected to the serial bus 22. Each of the high frequency ICs 23 is configured with the semiconductor device 2 described in any of the first to fourth embodiments. When each high frequency IC 23 is a high frequency switch, the selection among a plurality of RF signal terminals is possible. The control IC 24 supplies a power potential Vdd_1 and a clock signal CK to each high frequency IC 23. Each high frequency IC 23 converts serial data DATA into parallel data and, when each is a high frequency switch, it selects one of the RF signal terminals based on the logic of the parallel data.

As the number of the high frequency ICs 23 increases, the number of switchable RF signal terminals also increases. Therefore, the configuration of FIG. 11 can be easily compatible with multimode and multiband capabilities.

Moreover, as described above, each of the high frequency ICs 23 builds in the macro cell 10 capable of being commonly used, Therefore, the design and production costs for the high frequency ICs can be reduced.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor integrated circuit comprising:
a macro cell;
an initial voltage setting unit to generate initial data to be set in the macro cell; and
a data wiring section connected between the macro cell and the initial voltage setting unit so that the data wiring section is at a predetermined potential level.

2. The semiconductor integrated circuit of claim 1 further comprising a power-on reset unit to generate a power-on reset signal that is set to a predetermined signal logic when a predetermined time elapses after power is on,
wherein the initial voltage setting unit performs wiring of the data wiring sections so that the data wiring section is at a power supply potential; a ground potential or a potential of the power-on reset signal.

3. The semiconductor integrated circuit of claim 1, wherein the macro cell has a flip-flop that has at least one of a set terminal and a reset terminal,
wherein the initial voltage setting unit sets at least one of the data wiring section connected to the set terminal and the data wiring section connected to the reset terminal to a predetermined potential level.

4. The semiconductor integrated circuit of claim 1, wherein the initial voltage setting unit is provided in an area that is not overlapped with the macro cell.

5. The semiconductor integrated circuit of claim 1, wherein the initial voltage setting unit is provided in a predetermined area in the macro cell, the predetermined area being set to an automatic placement-and-routing prohibited area and being an area of no wiring in the macro cell except for the data wiring sections.

6. The semiconductor integrated circuit of claim 1, wherein the macro cell has a logical operation circuit to perform a predetermined logical operation using the initial data and the initial voltage setting unit connects the data wiring sections to a power supply line or a ground line.

7. A semiconductor device comprising:
a switch circuit to select one of a plurality of high frequency signals based on a parallel switching control signal; and
a switching control circuit to generate the parallel switching control signal,
wherein the switching control circuit has a Serial-to-parallel converter circuit to convert a serial switching control signal to the parallel switching control signal,
wherein the serial-to-parallel converter circuit includes:
a macro cell;
an initial voltage setting unit to generate initial data to beset in the macro cell; and
a data wiring section connected between the macro cell and the initial voltage setting unit so that the data wiring section is at a predetermined potential level.

8. The semiconductor device of claim 7 further comprising a power-on reset unit to generate a power-on reset signal that is set to a predetermined signal logic when a predetermined time elapses after power is on,
wherein the initial voltage setting unit performs wiring of the data wiring section so that the data wiring section is at a power supply potential, a ground potential or a potential of the power on reset signal.

9. The semiconductor device of claim 7, wherein the macro cell has a flip-flop that has at least one of a set terminal and a reset terminal,
wherein the initial voltage setting unit sets at least one of the data wiring section connected to the set terminal and the data wiring section connected to the reset terminal to a predetermined potential level.

10. The semiconductor device of claim 7, wherein the initial voltage setting unit is provided in an area that is not overlapped with the macro cell.

11. The semiconductor device of claim 7, wherein the initial voltage setting unit is provided in a predetermined area in the macro cell, the predetermined area being set to an automatic placement-and-routing prohibited area and being an area of no wiring in the macro cell except for the data wiring section.

12. The semiconductor device of claim 7, wherein the macro cell has a logical operation circuit to perform a predetermined logical operation using the initial data and the initial voltage setting unit connects the data wiring section to a power supply line or a ground line.

13. A method of designing a semiconductor circuit comprising the steps of;
generating by an initial voltage setting unit initial data to be set in a macro cell; and
connecting a data wiring section between the macro cell and the initial voltage setting unit so that the data wiring section is at a predetermined potential level, by automatic placement and routing.

14. The method of claim 13 further comprising generating a power-on reset signal that is set to a predetermined signal logic when a predetermined time elapses after power is on,
wherein the wiring of the data wiring section is performed so that the data wiring section is at a power supply potential, a ground potential or a potential of the power-on reset signal,

15. The method of claim 13, wherein the macro cell has a flip-flop that has at least one of a set terminal and a reset terminal,
wherein the at least one of the data wiring section connected to the set terminal and the data wiring section connected to the reset terminal to a predetermined potential level is set.

16. The method of claim 13, wherein the initial voltage setting unit is provided in an area that is not overlapped with the macro cell.

17. The method of claim 13, wherein the initial voltage setting unit is provided in a predetermined area in the macro cell, the predetermined area being set to an automatic placement-and-routing prohibited area and being an area of no wiring in the macro cell except for the data wiring section.

18. The method of claim 13, wherein the macro cell is provided with a logical operation circuit to perform a predetermined logical operation using the initial data and the initial voltage setting unit connects the data wiring section to a power supply line or a ground line.

19. The method of claim 13, wherein the macro cell is commonly used by a plurality of semiconductor circuits to be designed.

20. The method of claim 19, the initial data having a potential level unique to one another is set to each of a plurality of semiconductor circuits to be designed.
